(19) United States
(12) Patent Application Publication
(10) Pub. No.: US 2024/0377851 A1
(43) Pub. Date: Nov. 14, 2024

(54) SEMICONDUCTOR DEVICE

(71) Applicant: Nuvoton Technology Corporation Japan, Kyoto (JP)

(72) Inventors: Satoshi ENDO, Osaka (JP); Takuya ISHII, Osaka (JP); Hitoshi KOBAYASHI, Osaka (JP); Kazuhito ITO, Osaka (JP); Shuichi OGATA, Osaka (JP)

(21) Appl. No.: 18/781,507

(22) Filed: Jul. 23, 2024

Related U.S. Application Data
(63) Continuation of application No. PCT/JP2023/002372, filed on Jan. 26, 2023.

(30) Foreign Application Priority Data
Feb. 1, 2022 (JP) 2022-014202

(51) Int. Cl. G05F 1/56; H01L 23/00; H01L 23/31; H01L 23/495; H01L 25/065

(52) U.S. Cl. CPC G05F 1/56; H01L 23/49555; H01L 25/0657; H01L 23/3107; H01L 24/16; H01L 24/32; H01L 24/48; H01L 24/73; H01L 2224/16145; H01L 2224/32245; H01L 2224/48175; H01L 2224/73207; H01L 2224/73253; H01L 2224/73265; H01L 2225/06568

(57) ABSTRACT

A semiconductor device includes: a lead frame; a first semiconductor chip mounted face-up above the lead frame; and a second semiconductor chip mounted face-down above the first semiconductor chip. The second semiconductor chip has a chip size smaller than a chip size of the first semiconductor chip. The second semiconductor chip includes a bandgap element (an NPN transistor, an N-parallel NPN transistor) including a positive-negative (PN) junction and included in a band gap reference circuit.

### CROSS REFERENCE TO RELATED APPLICATIONS

This is a continuation application of PCT International Application No. PCT/JP2023/002372 filed on Jan. 26, 2023, designating the United States of America, which is based on and claims priority of Japanese Patent Application No. 2022-014202 filed on Feb. 1, 2022. The entire disclosures of the above-identified applications, including the specifications, drawings and claims are incorporated herein by reference in their entirety.

### FIELD

The present disclosure relates to semiconductor devices, and in particular to a technique suitable for a band gap reference circuit and peripheral circuits thereof that inhibit the effects of stress fluctuations.

### BACKGROUND

A conventional band gap reference circuit that inhibits the effects of stress fluctuations is disclosed, for example, in Patent Literature (PTL) 1. Stress fluctuations are fluctuations of stress in a semiconductor package (hereinafter also referred to simply as “package”) caused by fluctuations in external environmental conditions such as temperature and humidity. A band gap reference circuit is a circuit that uses a band gap voltage to cause an output having a negative temperature coefficient and an output having a positive temperature coefficient to cancel each other and output a constant voltage. In PTL 1, a plurality of reference voltage generation sources are connected in parallel, and an average value of the outputs of the plurality of reference voltage generation sources is used as an output. In addition, an output from a reference voltage generation source, among the plurality of reference voltage generation sources, that outputs a value deviating from a desired output value of the band gap reference circuit is blocked, thereby achieving high accuracy. In addition, the plurality of reference voltage generation sources are symmetrically arranged throughout the chip in layout to provide a configuration that is resistant to stress fluctuations and thermal distribution fluctuations.

### CITATION LIST

### Patent Literature

PTL 1: Japanese Unexamined Patent Application Publication No. 11-40749

### SUMMARY

### Technical Problem

The conventional technique described above requires a plurality of reference voltage generation sources, and the plurality of reference voltage generation sources are distributed on the chip, resulting in complicated wiring and an increase in semiconductor chip area.

In view of the above, an object of the present disclosure is to provide a semiconductor device having a configuration that is small in overall size and alleviates stress fluctuations in a package, and including a circuit that outputs a highly accurate and highly stable reference voltage.

### Solution to Problem

In view of the above, a semiconductor device according to one aspect of the present disclosure includes: a lead frame; a first semiconductor chip mounted face-up above the lead frame; and a second semiconductor chip mounted face-down above the first semiconductor chip, the second semiconductor chip having a chip size smaller than a chip size of the first semiconductor chip. In the semiconductor device, the second semiconductor chip includes a bandgap element including a positive-negative (PN) junction and included in a band gap reference circuit.

### Advantageous Effects

According to the present disclosure, a semiconductor device having a configuration that is small in overall size and alleviates stress fluctuations in a package, and including a circuit that outputs a highly accurate and highly stable reference voltage is implemented.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram illustrating a configuration of a semiconductor device according to an embodiment.

FIG. 2 is a circuit block diagram of the semiconductor device according to Embodiment 1.

FIG. 3 is a circuit diagram illustrating a power supply circuit of the semiconductor device according to Embodiment 1.

FIG. 4 is a circuit diagram illustrating one example of a band gap reference circuit of the semiconductor device according to Embodiment 1.

FIG. 5 is a diagram illustrating a portion of a band gap reference circuit in a semiconductor device and an example of eFuse blowing according to Embodiment 2.

FIG. 6 is a circuit diagram illustrating a band gap reference circuit in a semiconductor device according to Embodiment 3.

FIG. 7 is an operational waveform diagram of the band gap reference circuit in the semiconductor device according to Embodiment 3.

FIG. 8A is a circuit block diagram illustrating a circuit that is mounted on a first semiconductor chip in the semiconductor device according to Embodiment 3.

FIG. 8B is an operational waveform diagram of the semiconductor device according to Embodiment 3.

FIG. 9 is a circuit block diagram illustrating the semiconductor device according to Embodiment 4.

FIG. 10 is a main circuit block diagram of a second semiconductor chip of a semiconductor device according to Embodiment 5.

FIG. 11 is a layout diagram of a second semiconductor chip of a semiconductor device according to Embodiment 6.

### DESCRIPTION OF EMBODIMENTS

The following describes in detail embodiments according to the present disclosure, with reference to the drawings. It should be noted that each of the exemplary embodiments described below shows one specific example of the present disclosure. The numerical values, shapes, materials, structural components, the arrangement and connection of the structural components, signal waveforms, signal timing, etc. described in the following embodiments are mere examples, and therefore do not limit the scope of the present disclosure. In addition, the respective diagrams are not necessarily precise illustrations. Throughout the drawings, the same reference sign is given to substantially the same structural component, and redundant description will be omitted or simplified.

Hereinafter, a semiconductor device according to embodiments will be described with reference to the drawings.

### Embodiment 1

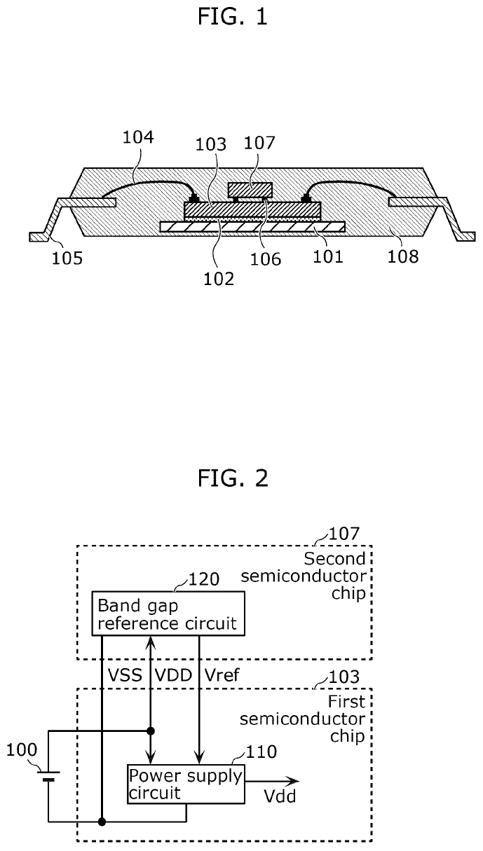

FIG. 1 is a diagram illustrating a configuration of a semiconductor device according to an embodiment. It should be noted that the configuration of the semiconductor device illustrated in this diagram is common to the semiconductor devices according to Embodiment 1 to Embodiment 6. In FIG. 1, the semiconductor device according to the present embodiment includes lead frame 101, conductive paste 102, first semiconductor chip 103, bonding wire 104, pin terminal 105, connection terminal 106, second semiconductor chip 107, and sealing resin 108. First semiconductor chip 103 is adhered in a face-up disposition to the die pad of lead frame 101 on which conductive paste 102 is applied, and is electrically connected to pin terminal 105 using bonding wire 104 to input and output signals to and from the outside. Second semiconductor chip 107 is mounted face-down above first semiconductor chip 103 using connection terminal 106, has a chip size smaller than a chip size of first semiconductor chip 103, and inputs and outputs signals to and from first semiconductor chip 103 via connection terminal 106. At least first semiconductor chip 103 and second semiconductor chip 107 are sealed in a single package by sealing resin 108. Connection terminal 106 is a terminal provided to each of first semiconductor chip 103 and second semiconductor chip 107. The total number of connection terminals 106 is not shown in FIG. 1. The total number of connection terminals 106 may be three or more.

FIG. 2 is a circuit block diagram of the semiconductor device according to Embodiment 1. In this diagram, pin terminals and wire bonds are omitted. FIG. 2 illustrates only: power supply circuit 110 included in first semiconductor chip 103 and band gap reference circuit 120 included in second semiconductor chip 107 as main circuit blocks; and their connection relationships. Input power supply voltage VDD (hereinafter also referred to as “input direct current (DC) voltage VDD”) and ground voltage VSS (hereinafter also referred to as “ground VSS”) which have been input from DC power supply 100 disposed outside the semiconductor device are both supplied to power supply circuit 110 of first semiconductor chip 103, and are also supplied from first semiconductor chip 103 to band gap reference circuit 120 included in second semiconductor chip 107 via connection terminals 106 (respectively, power supply terminal VDD and power supply terminal VSS that is a reference terminal of power supply terminal VDD). It should be noted that power supply terminal VDD and power supply terminal VSS are examples of a power supply terminal and a first ground terminal, respectively, for supplying input power supply voltage VDD.

Band gap reference circuit 120 generates reference voltage Vref from input power supply voltage VDD. Reference voltage Vref is output to power supply circuit 110 included in first semiconductor chip 103 via another connection terminal 106. Power supply circuit 110 generates power supply voltage Vdd from input power supply voltage VDD using reference voltage Vref, and supplies power to each of the other circuits included in first semiconductor chip 103.

Here, reference voltage Vref is required to be small in fluctuation and variation, and band gap reference circuit 120 is configured with various ingenuities described below to generate a stable reference voltage against temperature fluctuations. On the other hand, other than temperature fluctuations, factors that cause fluctuations in reference voltage Vref include stress due to package warpage, etc. This is because the piezo resistance effect in which resistance changes due to stress affects the characteristics of a bipolar transistor which is a main circuit element of the bandgap reference circuit. Factors that cause package warpage, etc. include the difference in the thermal expansion coefficient between the semiconductor chip and the sealing resin, and by reducing the contact area between the semiconductor chip and the sealing resin, it can be expected that stress fluctuations are alleviated. In the present disclosure, second semiconductor chip 107 has a minimum configuration including band gap reference circuit 120 to reduce the area, and is flip-chip mounted facing first semiconductor chip 103, thereby alleviating stress fluctuations due to package warpage, etc.

The following describes the details of power supply circuit 110 and band gap reference circuit 120.

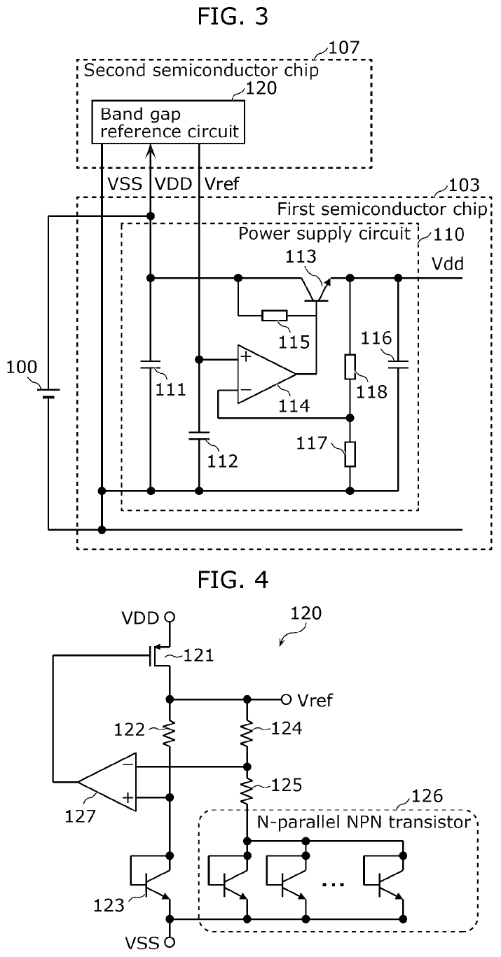

First, an example of the configuration of power supply circuit 110 will be described with referenced to FIG. 3. FIG. 3 is a circuit diagram illustrating power supply circuit 110 of the semiconductor device according to Embodiment 1. More specifically, FIG. 3 is a circuit diagram illustrating one example of power supply circuit 110 included in first semiconductor chip 103. In power supply circuit 110, input power supply voltage VDD is received by capacitor 111 and applied to the collector terminal of negative-positive-negative (NPN) transistor 113. Reference voltage Vref is received by capacitor 112 and applied to the non-inverting input terminal of amplifier 114. A base current is supplied to the base terminal of NPN transistor 113 from input power supply voltage VDD via resistor 115, and power supply voltage Vdd is output from the emitter terminal of NPN transistor 113. Power supply voltage Vdd is smoothed by capacitor 116 and supplied to each of the circuits included in first semiconductor chip 103, and is divided by resistor 117 and resistor 118 to be applied to the inverting input terminal of amplifier 114. As described above, power supply circuit 110 constitutes a series regulator, and when the resistance value of resistor 117 is denoted by R17 and the resistance value of resistor 118 is denoted by R18, power supply voltage Vdd that is output is expressed by the following equation and is proportional to reference voltage Vref.

Vdd=(1+R18/R17)·Vref

As described above, when reference voltage Vref is highly accurate and highly stable with less fluctuation, power supply voltage Vdd that is output by power supply circuit 110 and supplied to each of the circuits included in first semiconductor chip 103 is likewise highly accurate and highly stable, and thus the operation of each of the circuits to which power is supplied is stabilized.

Next, an example of the configuration of band gap reference circuit 120 will be described with referenced to FIG. 4. FIG. 4 is a circuit diagram illustrating one example of band gap reference circuit 120 of the semiconductor device according to Embodiment 1. The current flowing through current supplying P-channel metal oxide semiconductor (PMOS) transistor 121 to which input power supply voltage VDD is applied is divided into a first series circuit of resistor 122 and NPN transistor 123 and a second series circuit of resistor 124, resistor 125, and N-parallel NPN transistor 126. It should be noted that NPN transistor 123 and N-parallel NPN transistor 126 are examples of the bandgap elements including a positive-negative (PN) junction and included in bandgap reference circuit 120.

It is assumed that the resistance values of resistor 122 and resistor 124 are currently equal (the resistance value is assumed to be r), and that the resistance value of resistor 125 is R. NPN transistor 123 has a diode configuration in which the collector terminal and the base terminal are connected, and its base-emitter voltage is assumed to be Vbe1. N-parallel NPN transistor 126 includes N transistors of the same configuration as NPN transistor 123 which are connected in parallel, and its base-emitter voltage is assumed to be Vbe2. The inverting input terminal and the non-inverting input terminal of amplifier 127 are connected to the connection point of resistor 122 and NPN transistor 123 and the connection point of resistor 124 and resistor 125, respectively, and the output terminal of amplifier 127 is connected to the gate terminal of current supplying PMOS transistor 121. Here, current supplying PMOS transistor 121, resistor 122, resistor 124, and amplifier 127 constitute a negative feedback loop, and the inverting input terminal and the non-inverting input terminal of amplifier 127 are at the same potential. Accordingly, a current of the same value flows in the first series circuit and second the series circuit. Here, Vbe1−Vbe2=(kT/q)InN is satisfied where Boltzmann's constant is denoted by k, an absolute temperature is denoted by T, and electron charge is denoted by q. In is the natural logarithm. Accordingly, output voltage Vref of band gap reference circuit 120 is Vref=Vbe1+(r/R)·(kT/q)InN. Thus, by setting resistance ratio r/R and the total number of parallel connections N of N-parallel NPN transistor 126 to appropriate values, the negative temperature coefficient (for example, −2 mV/° C.) of base-emitter voltage Vbe1 of NPN transistor 123 can be canceled and a stable output voltage can be obtained against temperature fluctuations.

In the present disclosure, stress fluctuations due to package warpage, etc. are suppressed in second semiconductor chip 107 in which band gap reference circuit 120 is included. In other words, it is possible to provide band gap reference circuit 120 that supplies a stable reference voltage against temperatures and stress which are factors that cause voltage fluctuations.

It should be noted that, although band gap reference circuit 120 is included in second semiconductor chip 107 in the present disclosure, the configuration of the present disclosure for achieving the advantageous effect of alleviation of stress fluctuations is not limited to this configuration. It is sufficient if at least the band gap elements (in the present disclosure, NPN transistor 123 and N-parallel NPN transistor 126) included in band gap reference circuit 120 are included in second semiconductor chip 107.

As described above, the semiconductor device according to the present embodiment includes: lead frame 101; first semiconductor chip 103 mounted face-up above lead frame 101; and second semiconductor chip 107 mounted face-down above first semiconductor chip 103, second semiconductor chip 107 having a chip size smaller than a chip size of first semiconductor chip 103. In the semiconductor device, second semiconductor chip 107 includes a bandgap element (NPN transistor 123, N-parallel NPN transistor 126) including a positive-negative (PN) junction and included in band gap reference circuit 120.

According to this configuration, the semiconductor device includes first semiconductor chip 103 and second semiconductor chip 107 that is mounted above and smaller in size than first semiconductor chip 103. Second semiconductor chip 107 is minimized to a small area with a minimal configuration including a band gap element, and is flip-chip mounted facing first semiconductor chip 103. Accordingly, the overall size is reduced, stress fluctuations due to package warpage, etc. are alleviated, and as a result, a semiconductor device including a circuit that outputs a highly accurate and highly stable reference voltage is implemented.

More specifically, second semiconductor chip 107 includes band gap reference circuit 120 that receives input DC voltage VDD as an input to output reference voltage Vref, and first semiconductor chip 103 supplies input DC voltage VDD to second semiconductor chip 107 and second semiconductor chip 107 supplies reference voltage Vref to first semiconductor chip 103. As a result, second semiconductor chip 107 has a minimal configuration including band gap reference circuit 120, and thus the area of second semiconductor chip 107 is reduced and stress fluctuations due to package warpage, etc. are alleviated.

### Embodiment 2

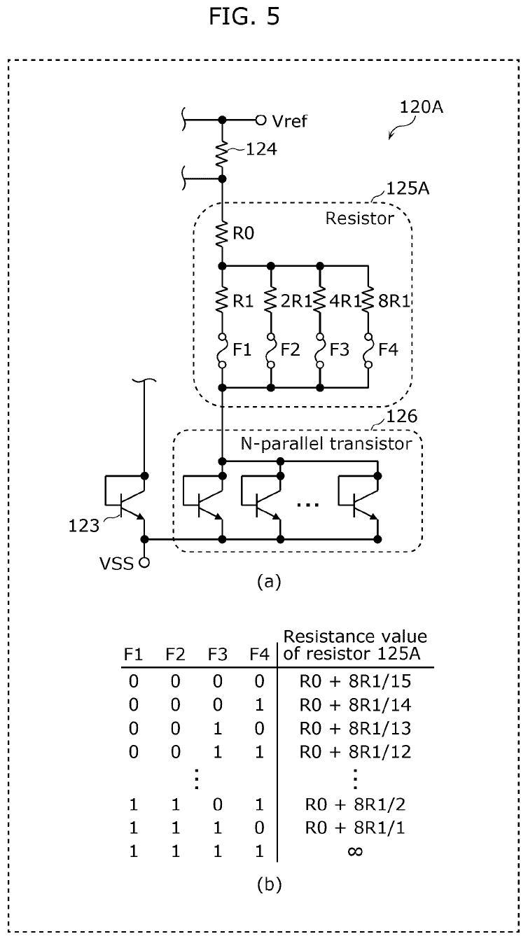

The band gap reference circuit of the present disclosure has stable characteristics against temperature and stress which are factors that cause fluctuations in reference voltage Vref that is an output. Here, a method of inhibiting variations in reference voltage Vref caused by variations in the characteristics of the structural components will further be described. FIG. 5 is a diagram illustrating a portion of band gap reference circuit 120A in a semiconductor device according to Embodiment 2 ((a) of FIG. 5) and an example of eFuse blowing ((b) of FIG. 5). In other words, the circuit illustrated in (a) of FIG. 5 is one example of a circuit configuration that fine-tunes reference voltage Vref that is the output of band gap reference circuit 120 according to Embodiment 1, and is referred to as band gap reference circuit4 120A in order to distinguish it from band gap reference circuit 120 illustrated in FIG. 4.

Band gap reference circuit 120A illustrated in (a) of FIG. 5 includes resistor 125A which is different in configuration from resistor 125 of band gap reference circuit 120 illustrated in FIG. 4. The resistance value of resistor 125A is adjusted by eFuses F1 to F4. In (a) of FIG. 5, resistor 125A includes a parallel circuit including: a series circuit of a resistor with resistance value R1 and eFuse F1connected in series to a resistor with resistance value R0; a series circuit of a resistor with resistance value 2R1 and eFuse F2; a series circuit of a resistor with resistance value 4R1 and eFuse F3; and a series circuit of a resistor with resistance value 8R1 and eFuse F4. Resistance value R of resistor 125A is, for example, R=R0+1/{1/R1+1/(2R1)+1/(8R1)}=R0+8R1/13 when only eFuse F3 out of eFuses F1 to F4 is blown, and R=R0+4R1=R0+8R1/2 when eFuses other than eFuse F3 among F1 to F4 are blown. For each of eFuses F1 to F4, the case where the eFuse is not blown is represented by “0” and the case where the eFuse is blown is represented by “1”, and the resistance value of resistor 125A is calculated for (F1, F2, F3, F4)= (0, 0, 0, 0, 0) to (1, 1, 1, 1, 1). The result of this calculation is shown in (b) of FIG. 5. In other words, the resistance value of resistor 125A can be set in 15 different resistance values from R0+8R1/15 to R0+8R1/1, except the case of (1,1,1,1) where all of the eFuses are blown and the resistance value of resistor 125A is in infinite.

As described above, band gap reference circuit 120A measures reference voltage Vref that is output by applying input power supply voltage VDD, and input blowing signals (F1, F2, F3, F4) of eFuses F1 to F4 to the blowing circuit (not illustrated) so as to bring reference voltage Vref closer to the target value, thereby allowing trimming to fine-tune reference voltage Vref.

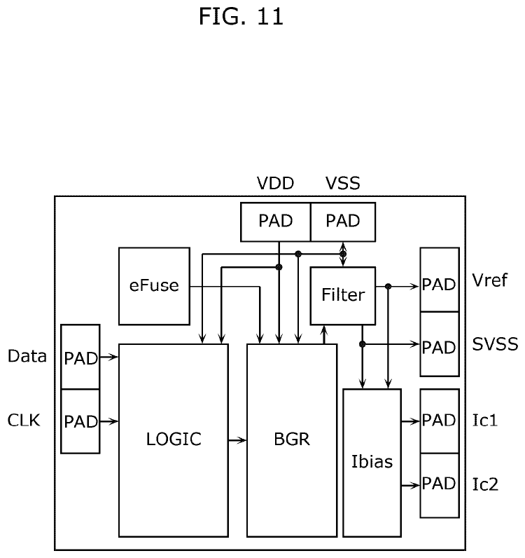

Second semiconductor chip 107 requires inspection terminals including input terminals for trimming information (e.g., a data terminal and a clock terminal of an inter-integrated circuit (I2C) (input terminals Data and CLK described below with referenced to FIG. 11)). However, these inspection terminals are not connected to first semiconductor chip 103 and have configurations different from the configuration of connection terminals 106. In addition, a storage circuit that holds the trimming information that has been input is provided (see the LOGIC) section illustrated in FIG. 11). Furthermore, a blowing circuit that blows eFuses F1 to F4 according to the trimming information held in the storage circuit is also provided. This makes it possible to inspect and adjust only second semiconductor chip 107 in the process prior to connection with first semiconductor chip 103. In this manner, by completing the inspection and adjustment of second semiconductor chip 107 in second semiconductor chip 107, the following two advantageous effects are yielded.

One advantageous effect is the alleviation of stress generated from the difference in thermal expansion of connection materials due to not increasing the total number of connection terminals between first semiconductor chip 103 and second semiconductor chip 107. Inhibiting fluctuations of the reference voltage, etc. by stress alleviation is an essence of the present disclosure. However, the difference in thermal expansion coefficients between the connection terminals and the interchip sealing resin is another factor that causes stress on second semiconductor chip 107, and thus, for example, the total number of connection terminals is minimized.

Another advantageous effect is the reduction of inspection time by conducting the inspection of second semiconductor chip 107 with a plurality of chips at the same time, in the process before second semiconductor chip 107 is mounted on first semiconductor chip 103. In the inspection and adjustment process, voltage information at a plurality of temperatures such as high, normal, and low temperatures and the optimal trimming information according to the voltage information are set. If this is conducted in the package inspection after mounting on first semiconductor chip 103, the inspection time would increase because the measurement of a plurality of items at the same time as in the chip inspection is not possible.

It should be noted that, the illustration of the blowing circuit that receives blowing signals (F1, F2, F3, F4) as inputs and blows the eFuse designated is omitted because it is not the essence of present disclosure and is also complicated. In addition, the eFuse described above is one example of fine-tuning, and thus the present disclosure is not limited to this configuration. There are other ways to use switch elements, etc. other than the eFuse to adjust each parameter including the resistance value, and in such cases, the means to hold inspection data including trimming information is also effective.

As described above, in the semiconductor device according to the present embodiment, second semiconductor chip 107 includes: input terminal Data through which trimming information for adjusting reference voltage Vref output by band gap reference circuit 120A is input; and storage circuit (LOGIC section) for holding the trimming information. According to this configuration, it is possible to inspect second semiconductor chip 107 with a plurality of chips at the same time, and receive trimming information as an input. As a result, inspection and adjustment time is reduced.

### Embodiment 3

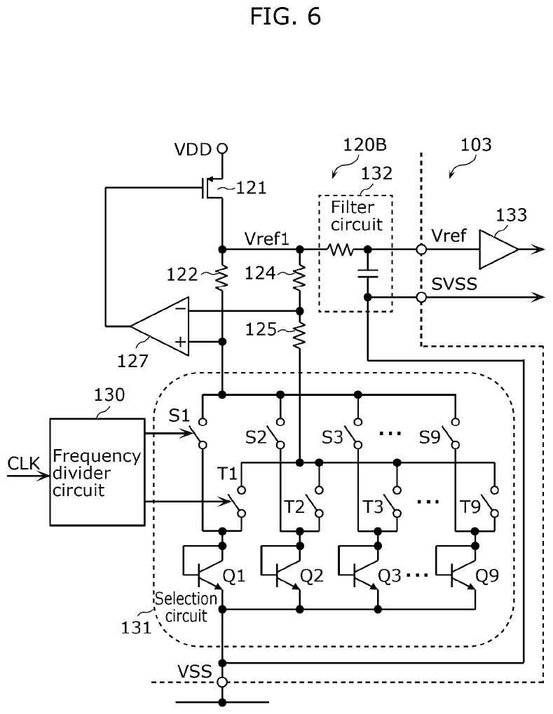

One factor that causes variation in reference voltage Vref output by band gap reference circuit is the variation of base-emitter voltage Vbe of the transistor. In Embodiment 3, this variation is inhibited. FIG. 6 is a circuit diagram illustrating band gap reference circuit 120B in a semiconductor device according to Embodiment 3. In other words, FIG. 6 illustrates, as band gap reference circuit 120B according to the present disclosure, an example of the configuration in which a technique of inhibiting variation of base-emitter voltage Vbe by receiving, as an input, signal CLK which is an “H” pulse at a predetermined period from first semiconductor chip 103 is applied to band gap reference circuit 120 according to Embodiment 1. Band gap reference circuit 120 illustrated in FIG. 4 has a configuration in which NPN transistor 123 and N-parallel NPN transistor 126 including N transistors in parallel are included. In contrast, band gap reference circuit 120B illustrated in FIG. 6 includes frequency divider circuit 130 which receives signal CLK as an input, and further includes: selection circuit 131 including switches S1 to S9 and T1 to T9 which are turned on and off by a frequency divider signal that is output by frequency divider circuit 130, and NPN transistors Q1 to Q9 connected thereto; and filter circuit 132. Selection circuit 131 is one example of a circuit that periodically switches the combination of devices to be used among the plurality of devices (NPN transistors Q1 to Q9) according to a clock signal (more strictly, the frequency divider signal output by frequency divider circuit 130 that is operated by the clock signal).

An input voltage to filter circuit 132 is referred to as pre-reference voltage Vref1. Pre-reference voltage Vref1 is input to buffer circuit 133 included in first semiconductor chip 103 through filter circuit 132, and reference voltage Vref is supplied from buffer circuit 133. For the convenience of explanation, the divider signal is assigned with the same reference sign as the switch to be driven.

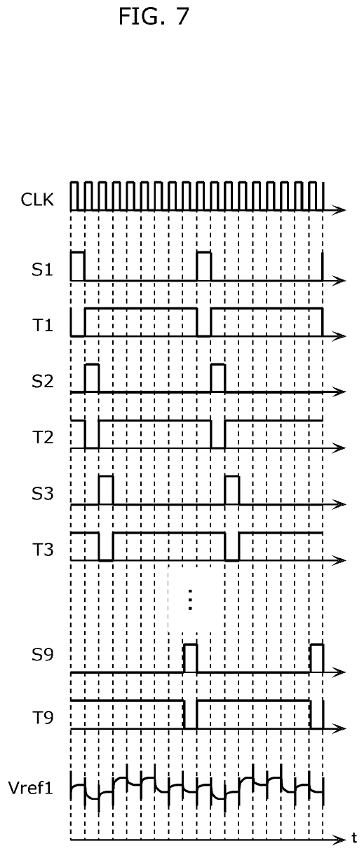

FIG. 7 is an operational waveform diagram of band gap reference circuit 120B in the semiconductor device according to Embodiment 3. More specifically, FIG. 7 illustrates signal CLK input to frequency divider circuit 130, divider signals S1 to S9 and T1 to T9 which are output, and pre-reference voltage Vref1 input to filter circuit 132. It should be noted that frequency divider signals S1 to S9 and T1 to T9 are control signals for switches S1 to S9 and T1 to T9, respectively. Switches S1 to S9 and T1 to T9 are switched on when the frequency divider signal is at an “H” level. The following describes the operation of the present embodiment with reference to FIG. 6 and FIG. 7.

In the first period of signal CLK illustrated in FIG. 7, only switch S1 is at “H” among switches S1 to S9, and only switch T1 is at “L” among switches T1 to T9. Therefore, NPN transistor Q1 is connected to resistor 122, and NPN transistors Q2 to Q9 are connected to resistor 125. In the next period of signal CLK, only switch S2 is at “H” among switches S1 to S9, and only switch T2 is at “L” among switches T1 to T9. Therefore, NPN transistor Q2 is connected to resistor 122, and NPN transistors Q1 and Q3 to Q9 are connected to resistor 125. Thereafter, the transistors are connected to resistor 122 one by one in sequence, and the other eight transistors are connected to resistor 125. In other words, selection circuit 131 sequentially connects nine different combinations of transistors that are 1:8 using nine transistors. Pre-reference voltage Vref1 generated in each period varies slightly according to the variations in the characteristics of each transistor and has switching noise associated with switching of the switches.

Filter circuit 132 constitutes a low-pass filter including a resistor and a capacitor as illustrated in FIG. 6, for example. Filter circuit 132 averages pre-reference voltage Vref1 and inhibits switching noise, and outputs reference voltage Vref as a differential voltage with dedicated ground voltage SVSS (hereinafter also referred to as “dedicated ground SVSS”) through output terminal Vref included in connection terminal 106 and output terminal SVSS that is a reference terminal of output terminal Vref. Output terminal Vref and output terminal SVSS are examples of a reference voltage terminal and a second ground terminal, respectively, for outputting reference voltage Vref.

As illustrated in FIG. 6, reference voltage Vref output from second semiconductor chip 107 is supplied via buffer circuit 133 on first semiconductor chip 103. In order to avoid leading pre-reference voltage Vref1 on which noise is superimposed from second semiconductor chip 107 to first semiconductor chip 103 via connection terminal 106, filter circuit 132 is provided on second semiconductor chip 107 and buffer circuit 133 is provided on first semiconductor chip 103 side.

As described above, according to the present embodiment, by using an average value of nine transistors as the base-emitter voltage which is the main setting element of reference voltage Vref, the variation of the base-emitter voltage is inhibited. The technique of correcting manufacturing variations in a unit element included in the configuration by using the average of the characteristics of a plurality of elements is called dynamic element matching (DEM). In the embodiments of the present disclosure, the circuits necessary for DEM (the frequency divider circuit, the selection circuit, and the filter circuit in the present embodiment) are provided on second semiconductor chip 107, and signal CLK is transmitted from first semiconductor chip 103, thereby allowing reference voltage Vref with low noise and inhibited variation to be supplied to each circuit included in first semiconductor chip 103, in addition to achieving the effect of inhibiting stress fluctuations.

As described above, in the semiconductor device according to the present embodiment, first semiconductor chip 103 and second semiconductor chip 107 include, as a terminal connecting each other, a clock terminal (input terminal CLK illustrated in FIG. 11) for supplying a clock signal from first semiconductor chip 103 to second semiconductor chip 107, and band gap reference circuit 120B includes a plurality of devices (NPN transistors Q1 to Q9) for use in outputting reference voltage Vref, and selection circuit 131 that periodically switches the combination of the devices to be used among the plurality of devices according to clock signal CLK. According to this configuration, it is possible to average, etc., the variation of base-emitter voltage Vbe of the plurality of devices (NPN transistors Q1 to Q9), and in addition to achieving the effect of inhibiting stress fluctuations, it is possible to supply reference voltage Vref with low noise and inhibited variation.

In addition, first semiconductor chip 103 and second semiconductor chip 107 include, as a terminal connecting each other, a power supply terminal (power supply terminal VDD), a first ground terminal (power supply terminal VSS), a reference voltage terminal (output terminal Vref), and a second ground terminal (output terminal SVSS), input DC voltage VDD is supplied from first semiconductor chip 103 to second semiconductor chip 107 via the power supply terminal (power supply terminal VDD) and the first ground terminal (power supply terminal VSS) included in first semiconductor chip 103 and second semiconductor chip 107, and reference voltage Vref is supplied from second semiconductor chip 107 to first semiconductor chip 103 via the reference voltage terminal (output terminal Vref) and the second ground terminal (output terminal SVSS) included in first semiconductor chip 103 and second semiconductor chip 107. As a result, since reference voltage Vref is supplied using the second ground terminal (output terminal SVSS) as the reference terminal which is different from the first ground terminal (power supply terminal VSS) where potential fluctuation and noise superposition can occur, a highly accurate and low-noise reference voltage Vref can be obtained.

In addition, band gap reference circuit 120B includes filtering circuit 132 that outputs reference voltage Vref. According to this configuration, it is possible to inhibit the generation of noise due to periodic switching of the combination of the devices to be used among the plurality of devices according to clock signal CLK.

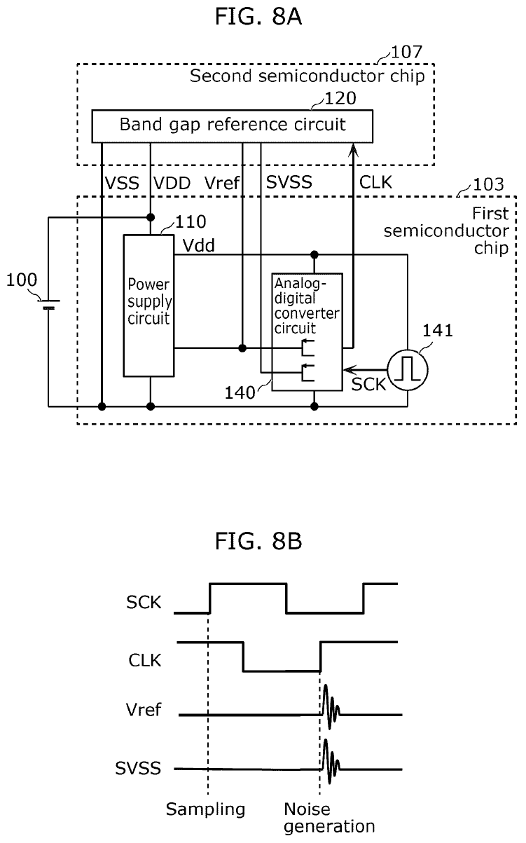

FIG. 8A is a circuit block diagram illustrating a circuit that is mounted on first semiconductor chip 103 of the semiconductor device according to Embodiment 3. As illustrated in FIG. 8A, a circuit that uses reference voltage Vref on first semiconductor chip 103 includes, for example, analog-digital converter circuit (ADC) 140. In FIG. 8A, ADC 140 has a configuration that receives sampling clock signal SCK from oscillator 141, generates clock signal CLK synchronized with clock signal SCK and having a phase difference from clock signal SCK, and transmits clock signal CLK to second semiconductor chip 107.

FIG. 8B is an operational waveform diagram of the semiconductor device according to Embodiment 3. As illustrated in FIG. 8B, noise superimposed on reference voltage Vref and dedicated ground SVSS is generated at the rising of clock signal CLK. However, by shifting the timing of this noise generation and the sampling timing (sampling clock signal SCK), it is possible to inhibit the effect of noise superimposed on reference voltage Vref and dedicated ground SVSS in ADC 140. In addition, in ADC 140, the differential voltage between reference voltage Vref and dedicated ground SVSS is used as the actual reference voltage, and furthermore, both reference voltage Vref and dedicated ground SVSS have a gate input configuration, for example. The current supplied from input power supply voltage VDD to bandgap reference circuit 120B flows through ground VSS and includes a noise current that is inhibited by filter circuit 132. This current generates voltage fluctuations in the parasitic impedance including the connection terminal for ground VSS, and thus potential fluctuations and noise superposition can be generated between Vref and VSS. On the other hand, since the configuration between Vref and SVSS inhibits noise through filter circuit 132 and also has almost no current flow, voltage fluctuations due to parasitic impedance are inhibited and a highly accurate and low-noise reference voltage can be obtained.

Although filter circuit 132 is included in second semiconductor chip 107 so as to prioritize the noise inhibiting effect in the present embodiment, if the priority is to reduce the area of second semiconductor chip 107, filter circuit 132 may be included in first semiconductor chip 103. In such a case, for example, filter circuit 132 is placed near the connection terminal to reduce, as much as possible, pattern wiring on which noise is superimposed.

As described above, in the semiconductor device according to the present embodiment, first semiconductor chip 103 includes ADC 140 that receives reference voltage Vref, and clock signal CLK supplied from first semiconductor chip 103 to second semiconductor chip 107 is synchronized with a sampling period of ADC 140 with a phase difference. According to this configuration, it is possible to inhibit the effect of noise superimposed on reference voltage Vref and dedicated ground SVSS in ADC 140, and inhibit an output error of ADC 140.

### Embodiment 4

With a semiconductor device according to Embodiment 4, it is possible to easily determine anomaly of the band gap reference circuit. In the present embodiment, in order to determine whether the reference voltage output by the band gap reference circuit is a normal value or not, another similar band gap reference circuit is provided and the outputs of both circuits are compared. For example, the reference voltage output by the band gap reference circuit is determined as normal if the difference between the reference voltages output by the both circuits is less than or equal to a predetermined value, and determined as anomalous if the difference exceeds the predetermined value.

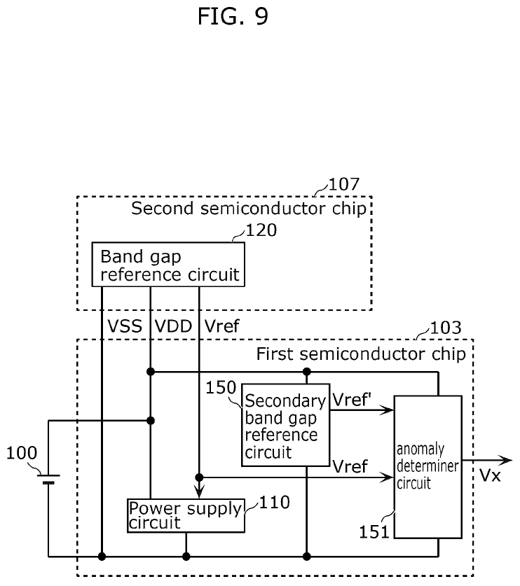

FIG. 9 is a circuit block diagram illustrating the semiconductor device according to Embodiment 4. More specifically, FIG. 9 is a circuit block diagram of a circuit having a function of determining anomaly of a reference voltage as Embodiment 4 of the present disclosure. In FIG. 9, the band gap reference circuit to be added is secondary band gap reference circuit 150, and its output is secondary reference voltage Vref′. Anomaly determiner circuit 151 is a circuit that compares reference voltage Vref output by band gap reference circuit 120 with secondary reference voltage Vref′ to determine whether it is normal or anomalous. Secondary band gap reference circuit 150 has the same circuit configuration as band gap reference circuit 120, but is included in first semiconductor chip 103 together with anomaly determiner circuit 151. This is because secondary reference voltage Vref′ output by secondary band gap reference circuit 150 is not required to be as accurate or stable as reference voltage Vref. When center values of reference voltage Vref and secondary reference voltage Vref′ are equally Vr, reference voltage Vref which is normal is Vr±ΔVr0 and secondary reference voltage Vref′ which is normal is Vr+ΔVr1. Based on fluctuations such as temperature, stress, and aging, as well as variations in the characteristics of the structural elements, ΔVr0 and ΔVr1 are assumed. If ΔVr0 is negligibly small compared to ΔVr1 because ΔVr0 can be set with high stability and high accuracy as described so far, reference voltage Vref is within the variation range of secondary reference voltage Vref′. In other words, anomaly determiner circuit 151, for example, determines that it is normal if the voltage difference between reference voltage Vref and secondary reference voltage Vref′ is less than or equal to ΔVr1, and that it is anomalous if the voltage difference exceeds ΔVr1.

As described above, in the semiconductor device according to the present embodiment, first semiconductor chip 103 includes secondary band gap reference circuit 150. First semiconductor chip 103 includes anomaly determiner circuit 151 that determines anomaly of reference voltage Vref by comparing reference voltage Vref with the output voltage from secondary band gap reference circuit 150. In this manner, it is possible to determine whether the reference voltage output by the band gap reference circuit has a normal value. In addition, since secondary band gap reference circuit 150 for which high accuracy is not required is included in first semiconductor chip 103, the increase in area of second semiconductor chip 107 is inhibited.

### Embodiment 5

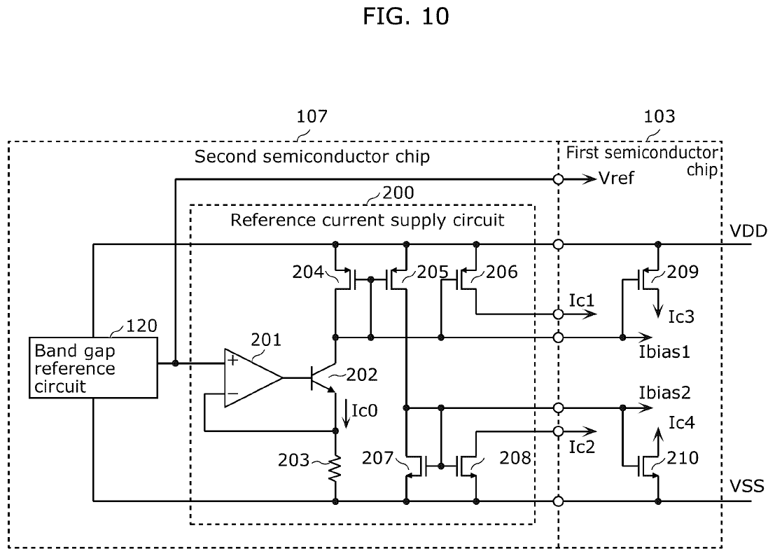

Embodiments 1 to 4 have described embodiments of providing a band gap reference circuit that generates a highly accurate and highly stable reference voltage by taking advantage of stress fluctuation alleviation to second semiconductor chip 107. Here, a reference current supply circuit that generates a reference current may be provided to second semiconductor chip 107. FIG. 10 is a main circuit block diagram of second semiconductor chip 107 of a semiconductor device according to Embodiment 5. More specifically, FIG. 10 is a diagram illustrating a circuit configuration in which reference current supply circuit 200 is provided. Reference current supply circuit 200 generates a reference current using reference voltage Vref output by band gap reference circuit 120 included in second semiconductor chip 107 according to Embodiment 1. Reference voltage Vref is applied to a non-inverting input terminal of amplifier 201, an output terminal of amplifier 201 is connected to the base of NPN transistor 202, an inverting input terminal of amplifier 201 is connected to an emitter terminal of NPN transistor 202. The emitter terminal of NPN transistor 202 is connected to resistor 203, and the other end of resistor 203 is connected to GND. The collector of NPN transistor 202 is connected to the drain and gate terminals of current supplying PMOS transistor 204, and power supply voltage Vcc is applied to the source terminal of current supplying PMOS transistor 204. Amplifier 201, NPN transistor 202, and resistor 203 constitutes a negative feedback loop, and the potential at the connection point between the base terminal of NPN transistor 202 and resistor 203 is reference voltage Vref. In other words, current Ic0 flowing from current supplying PMOS transistor 204 through NPN transistor 202 to resistor 203 is Ic0=Vref/R3 where the resistance value of resistor 203 is denoted by R3. PMOS transistor 205 and PMOS transistor 206 share the gate and source terminals with current supplying PMOS transistor 204 to constitutes a current mirror. The drain terminal of PMOS transistor 205 is connected to the drain and gate terminals of NMOS transistor 207, and the source terminal of NMOS transistor 207 is grounded to GND. NMOS transistor 208 shares the gate and source terminals with NMOS transistor 207 to constitutes a current mirror.

In the present embodiment, gate terminal Ibias1 of PMOS transistors 204 to 206, drain terminal Ic1 of PMOS transistor 206, gate terminal Ibias2 of NMOS transistors 207 to 208, and drain terminal Ic2 of NMOS transistor 208 are connected to first semiconductor chip 103 as current supply output terminals. It is assumed that constant current Ic1 flows out from terminal Ic1 and constant current Ic2 flows in from terminal Ic2. When each transistor size is the same, the current ratio of the current mirror; that is, a mirror ratio, is 1, and Ic0=Ic1=Ic2. On second semiconductor chip 107 in which stress fluctuations are alleviated and fluctuations in transistor characteristics are inhibited, fluctuations in the mirror ratio are also inhibited. In addition, although illustrations and detailed descriptions are omitted, resistance value R3 of resistor 203 can also be fine-tuned as with resistor 125A of band gap reference circuit 120A described above, and thus constant currents Ic1 and Ic2 with high accuracy and inhibited fluctuations and variations can be supplied to first semiconductor chip 103.

When the inhibiting of fluctuations of the mirror ratio is not required much, a current mirror of PMOS transistor 209 and NMOS transistor 210 may be included in first semiconductor chip 103 using terminals Ibias1 and Ibias2, as illustrated in first semiconductor chip 103 of FIG. 10.

As described above, in the semiconductor device according to the present embodiment, second semiconductor chip 107 includes reference current supply circuit 200 that generates a reference current using reference voltage Vref, and the reference current generated by reference current supply circuit 200 is supplied from second semiconductor chip 107 to first semiconductor chip 103. As a result, a highly accurate and highly stable reference current is supplied from second semiconductor chip 107 in addition to a highly accurate and highly stable reference voltage.

### Embodiment 6

FIG. 11 is a layout diagram of second semiconductor chip 107 which includes power supply terminals VDD and VSS, input terminals CLK and Data, output terminals Vref, SVSS, Ic1, and Ic2 as connection terminals with first semiconductor chip 103. It should be noted that input terminal CLK is one example of a clock terminal for second semiconductor chip 107 to receive a clock signal from first semiconductor chip 103.

In the diagram, the BGR section is a band gap reference circuit which generates pre-reference voltage Vref1 from input power supply voltage VDD from power supply terminal VDD and outputs pre-reference voltage Vref1 to the Filter section which is filter circuit 132 described in FIG. 6. The Filter section outputs reference voltage Vref with inhibited noise with respect to pre-reference voltage Vref1 to output terminals Vref and SVSS. The LOGIC section includes frequency divider circuit 130 and a switch section of selection circuit 131 described in FIG. 6, receives a clock signal from input terminal CLK and transmits the clock signal to NPN transistors Q1 to Q9 of selection circuit 131 of the BGR section. In addition, the LOGIC section includes a storage circuit (e.g., register) that stores inspection data including trimming information received through input terminal Data during inspection, and has an adjustment function such as blowing the eFuse of the eFuse section based on the trimming information. The Ibias section is reference current supply circuit 200 described in FIG. 10 which flows out constant current Ic1 through output terminal Ic1 and flows in constant current Ic2 through output terminal Ic2.

The LOGIC section performs switching operation according to clock signal CLK from input terminal CLK, and thus noise is generated. In order to improve the noise inhibiting effect in the Filter section, output terminals Vref and SVSS are not located near a noise generation source but are placed at a distance from the noise generation source, for example. Therefore, as illustrated in FIG. 11, input terminal CLK for a clock is disposed on an opposite side or a diagonal corner of second semiconductor chip 107 from output terminals Vref and SVSS or Ic1 and Ic2.

It should be noted that, although input power supply voltages VDD and VSS are supplied to each of the circuit sections illustrated in FIG. 11, the wiring to the BGR and LOGIC sections is mainly illustrated in FIG. 11 in order to avoid complication. Since the operating current is different in each circuit section, the power supply lines to each circuit section are provided separately from the terminal vicinity, as illustrated in FIG. 11, for example.

As described above, in the semiconductor device according to the present embodiment, the reference voltage terminal (output terminal Vref) and the second ground terminal (output terminal SVSS) are disposed on an opposite side or a diagonal corner of second semiconductor chip 107 from the clock terminal (input terminal CLK). As a result, the reference voltage terminal (output terminal Vref) and the second ground terminal (output terminal SVSS) are located away from a noise generation source caused by the switching operation according to clock signal CLK, thereby reducing the deterioration of the accuracy of reference voltage Vref due to noise.

It should be noted that second semiconductor chip 107 may have a dielectric isolation structure. The dielectric isolation structure is a structure in which a semiconductor element formation substrate is provided on a semiconductor support substrate via an inter-substrate insulation layer. The characteristics of a bipolar transistor used in a bandgap reference circuit is affected by leakage current due to thermal fluctuations. In other words, the dielectric isolation structure with low leakage current leads to high stability of the reference voltage which is the output of the band gap reference circuit.

Although the semiconductor device according to the present disclosure has been described so far based on Embodiments 1 to 6, the present disclosure is not limited to the above embodiments. Those skilled in the art will readily appreciate that various modifications may be made in these embodiments and that other embodiments may be obtained by arbitrarily combining the elements of these embodiments and working examples without materially departing from the novel teachings and advantages of the present disclosure. Accordingly, all such modifications and other embodiments are included in the present disclosure.

For example, ADC 140 according to Embodiment 3, secondary band gap reference circuit 150 and anomaly determiner circuit 151 according to Embodiment 4, and reference current supply circuit 200 according to Embodiment 5 may be provided in the semiconductor device according to Embodiment 1.

In addition, although the semiconductor device is provided with a band gap reference circuit according to the foregoing embodiments, it is not necessary to include a band gap reference circuit itself, but it is sufficient if a band gap element including a PN junction and included in the band gap reference circuit is included.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be used as a semiconductor device, in particular as a semiconductor device having a configuration that is small in overall size and alleviates stress fluctuations in a package, and including a circuit that outputs a highly accurate and highly stable reference voltage.

1. A semiconductor device comprising:
a lead frame;
a first semiconductor chip mounted face-up above the lead frame; and
a second semiconductor chip mounted face-down above the first semiconductor chip, the second semiconductor chip having a chip size smaller than a chip size of the first semiconductor chip, wherein
the second semiconductor chip includes a bandgap element including a positive-negative (PN) junction and included in a band gap reference circuit.

2. The semiconductor device according to claim 1, wherein
the band gap reference circuit included in the second semiconductor chip receives a DC voltage as an input to output a reference voltage,
the first semiconductor chip supplies the DC voltage to the second semiconductor chip, and
the second semiconductor chip supplies the reference voltage to the first semiconductor chip.

3. The semiconductor device according to claim 2, wherein
the second semiconductor chip includes:
an input terminal through which trimming information is input, the trimming information being for adjusting the reference voltage output by the band gap reference circuit; and
a storage circuit that holds the trimming information.

4. The semiconductor device according to claim 2, wherein
the first semiconductor chip and the second semiconductor chip include a clock terminal as a terminal connecting each other, the clock terminal being for supplying a clock signal from the first semiconductor chip to the second semiconductor chip, and
the band gap reference circuit includes:
a plurality of devices for use in outputting the reference voltage; and
a selection circuit that periodically switches a combination of devices to be used among the plurality of devices according to the clock signal.

5. The semiconductor device according to claim 4, wherein
the first semiconductor chip and the second semiconductor chip include a power supply terminal, a first ground terminal, a reference voltage terminal, and a second ground terminal, as terminals connecting each other,
the DC voltage is supplied from the first semiconductor chip to the second semiconductor chip via the power supply terminal and the first ground terminal included in the first semiconductor chip and the second semiconductor chip, and
the reference voltage is supplied from the second semiconductor chip to the first semiconductor chip via the reference voltage terminal and the second ground terminal collectively included in the first semiconductor chip and the second semiconductor chip.

6. The semiconductor device according to claim 5, wherein
the band gap reference circuit includes a filtering circuit that outputs the reference voltage.

7. The semiconductor device according to claim 5, wherein
the reference voltage terminal and the second ground terminal are disposed on an opposite side or a diagonal corner of the second semiconductor chip from the clock terminal.

8. The semiconductor device according to claim 4, wherein
the first semiconductor chip includes an analog-digital converter circuit that receives the reference voltage, and
the clock signal is synchronized with a sampling period of the analog-digital converter circuit with a phase difference.

9. The semiconductor device according to claim 2, wherein
the first semiconductor chip includes a secondary band gap reference circuit.

10. The semiconductor device according to claim 9, wherein
the first semiconductor chip includes an anomaly determiner circuit that determines an anomaly of the reference voltage by comparing the reference voltage with an output voltage from the secondary band gap reference circuit.

11. The semiconductor device according to claim 2, wherein
the second semiconductor chip includes a reference current supply circuit that generates a reference current using the reference voltage, and
the reference current generated by the reference current supply circuit is supplied from the second semiconductor chip to the first semiconductor chip.

12. The semiconductor device according to claim 2, wherein
the second semiconductor chip has a dielectric isolation structure.
